(19) United States
(12) Patent Application Publication
(10) Pub. No.: US 2020/0091064 A1
(43) Pub. Date: Mar. 19, 2020

(54) SEMICONDUCTOR DEVICE

(71) Applicant: TOSHIBA MEMORY CORPORATION, Minato-ku (JP)

(72) Inventors: Taichi IWASAKI, Yokkaichi (JP); Osamu Matsuura, Kuwana (JP); Takuya Inatsuka, Yokkaichi (JP)

(73) Assignee: TOSHIBA MEMORY CORPORATION, Minato-ku (JP)

(21) Appl. No.: 16/352,295

(22) Filed: Mar. 13, 2019

(30) Foreign Application Priority Data
Sep. 19, 2018 (JP) 2018-174553

(51) Int. Cl. H01L 23/528; H01L 27/105; H01L 23/532; H01L 23/522

(52) U.S. Cl. CPC H01L 23/528; H01L 23/5226; H01L 23/53257; H01L 27/1052

(57) ABSTRACT

According to one embodiment, there is provided a semiconductor device including a stacked body, a silicon nitride film, and a titanium film. The stacked body is disposed above a substrate. The stacked body includes a conductive layer and an insulating layer disposed repeatedly in a stacking direction. The silicon nitride film extends along a surface of the substrate between the substrate and the stacked body. The titanium film extends along the surface of the substrate between the substrate and the stacked body. The titanium film constitutes a film continuous with the silicon nitride film.

### CROSS-REFERENCE TO RELATED APPLICATIONS

This application is based upon and claims the benefit of priority from Japanese Patent Application No. 2018-174553, filed on Sep. 19, 2018; the entire contents of which are incorporated herein by reference.

### FIELD

Embodiments described herein relate generally to a semiconductor device.

### BACKGROUND

In some cases, a semiconductor device is configured such that a stacked body in which a conductive layer and an insulating film are alternately stacked is penetrated by a semiconductor pillar. At this time, it is desirable to increase the number of stacked layers in the stacked body to achieve high integration of the semiconductor device.

### BRIEF DESCRIPTION OF THE DRAWINGS

FIG. 1 is a cross-sectional view illustrating a configuration of a semiconductor device according to an embodiment;

FIG. 2 is a cross-sectional view illustrating a configuration of a continuous film of a silicon nitride film and a titanium film in the embodiment;

FIG. 3 is a plan view illustrating the configuration of the continuous film of the silicon nitride film and the titanium film in the embodiment;

FIGS. 4A to 4C are cross-sectional views illustrating a method of manufacturing the semiconductor device according to the embodiment;

FIGS. 5A to 5C are cross-sectional views illustrating the method of manufacturing the semiconductor device according to the embodiment;

FIG. 6 is a cross-sectional view illustrating a configuration of a continuous film of a silicon nitride film and a titanium film in Modified Example of the embodiment;

FIG. 7 is a plan view illustrating the configuration of the continuous film of the silicon nitride film and the titanium film in Modified Example of the embodiment; and

FIGS. 8A and 8B are cross-sectional views illustrating a method of manufacturing a semiconductor device according to Modified Example of the embodiment.

### DETAILED DESCRIPTION

In general, according to one embodiment, there is provided a semiconductor device including a stacked body, a silicon nitride film, and a titanium film. The stacked body is disposed above a substrate. The stacked body includes a conductive layer and an insulating layer disposed repeatedly in a stacking direction. The silicon nitride film extends along a surface of the substrate between the substrate and the stacked body. The titanium film extends along the surface of the substrate between the substrate and the stacked body. The titanium film constitutes a film continuous with the silicon nitride film.

Exemplary embodiments of a semiconductor device will be explained below in detail with reference to the accompanying drawings. The present invention is not limited to the following embodiments.

### Embodiment

In some cases, in a semiconductor device, a stacked body in which an insulating layer and a conductive layer are alternately stacked is penetrated by a semiconductor pillar and a gate insulating film covering a side surface of the semiconductor pillar to form a three-dimensional memory. Since this semiconductor device can increase the storage capacity by increasing the number of stacked layers, it is possible to reduce the necessity to use a more advanced patterning technique and to easily reduce the cost per bit. In this three-dimensional memory, each of portions where the conductive layers and the semiconductor pillars intersect each other is configured to function as a memory cell, and a memory cell array region in which a plurality of the memory cells are three-dimensionally disposed is configured.

In some cases, in order to further increase the integration density of the semiconductor device, a peripheral circuit region may be provided below the memory cell array region. In this case, after the peripheral circuit region is formed, the memory cell array region is formed. In the formation of the insulating layer and the interlayer insulating film in the memory cell array region, a material gas containing hydrogen such as silane is used. For this reason, in some cases, during or after the formation of the memory cell array region, hydrogen contained in the insulating layer or the interlayer insulating film may pass through contact plugs extending in the stacking direction and enter the peripheral circuit region.

For example, it is considered that hydrogen enters a semiconductor region functioning as a source region and/or a drain region connected to the contact plug. In a case where the semiconductor region contains P-type impurities (for example, boron or the like), there is a possibility that boron is inactivated due to hydrogen which has entered the semiconductor region being bonded to boron or the like. In a case where boron is inactivated and hard to function as an acceptor, it is difficult to make an ohmic contact between the contact plug and the semiconductor region, and thus, a Schottky barrier is formed at the contact interface, so that the transfer characteristic of the signal to the device including the semiconductor region is easily deteriorated. Similarly, in a case where the semiconductor region contains N-type impurities (for example, phosphorus or the like), there is a possibility that phosphorus is inactivated due to hydrogen which has entered the semiconductor region being bonded to phosphorus or the like. When phosphorus is inactivated and hard to function as a donor, it is difficult to make an ohmic contact between the contact plug and the semiconductor region, and thus, a Schottky barrier is formed at the contact interface, so that the transfer characteristic of the signal to a transistor including the semiconductor region is easily deteriorated.

Alternatively, for example, it is considered that hydrogen enters a polysilicon film functioning as a gate electrode connected to the contact plug or a gate insulating film below the polysilicon film. In a case where the gate electrode is a gate electrode of a PMOS transistor and the polysilicon film contains P-type impurities (for example, boron or the like), due to bonding of hydrogen which has entered the polysilicon film to boron and deterioration of a barrier property of a gate insulating film, the boron escapes to a substrate side, hump (a phenomenon in which a small peak appears in a Vg-Id curve of the transistor) occurs, and thus, there is a possibility that a threshold voltage and an off current Ioff is deviated and operation characteristics of the transistor are deteriorated.

Therefore, in the embodiment, in the semiconductor device, a continuous film of a silicon nitride film and a titanium film is disposed as a hydrogen barrier structure between the substrate and the stacked body in the stacking direction, and thus, entering of hydrogen into the peripheral circuit region is blocked to suppress deterioration in characteristic of the semiconductor device.

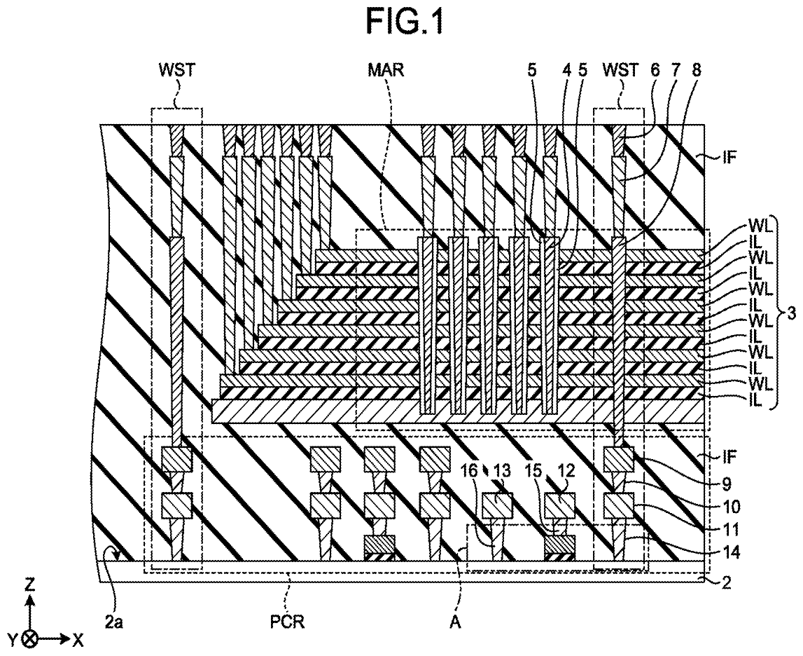

Specifically, a semiconductor device 1 can be configured as illustrated in FIG. 1. FIG. 1 is a cross-sectional view illustrating a configuration of the semiconductor device 1. In FIG. 1, a direction perpendicular to a surface 2a of a substrate 2 is defined as a Z direction, and two directions perpendicular to each other in the plane perpendicular to the Z direction are defined as an X direction and a Y direction. In addition, it is assumed that, a stacked body or the like constituting a main portion of the semiconductor device 1 is formed on the +Z side of the substrate 2.

The semiconductor device 1 includes a memory cell array region MAR, a peripheral circuit region PCR, and an interconnection wiring structure WST. The memory cell array region MAR is disposed on the +Z side of the peripheral circuit region PCR. The interconnection wiring structure WST is disposed from a position above (in the +Z side) the +Z-side end of the memory cell array region MAR in the Z direction to a Z position reaching the peripheral circuit region PCR.

The memory cell array region MAR includes a stacked body 3, a semiconductor pillar 4, and a gate insulating film 5. The stacked body 3 is disposed above the substrate 2 (in the +Z side). In the stacked body 3, a conductive layer WL and an insulating layer IL are repeatedly disposed in the stacking direction (Z direction). The semiconductor pillar 4 extends in the Z direction and penetrates the stacked body 3. The gate insulating film 5 covers a side surface of the semiconductor pillar 4, extends in the Z direction, and penetrates the stacked body 3. In the memory cell array region MAR, portions where the conductive layers WL and the semiconductor pillars 4 intersect each other are configured to function as memory cells, so that a plurality of the memory cells are three-dimensionally disposed. In addition, an interlayer insulating film IF is disposed around the memory cell array region MAR, including above and below the memory cell array region MAR.

The interconnection wiring structure WST functions as a wiring for electrically connecting the memory cell array region MAR and the peripheral circuit region PCR. For example, the interconnection wiring structure WST on the right side of FIG. 1 includes a plug 6, a plug 7, a penetration plug 8, a conductive film 9, a plug 10, conductive films 11 to 13, and contact plugs 14 to 16. Each of the plug 6, the plug 7, the penetration plug 8, the plug 10, and the contact plugs 14, 15, and 16 may be made of a material containing a conductive material (for example, tungsten) as a main component. A barrier metal is disposed on the side and bottom surfaces of each of the plug 6, the plug 7, the penetration plug 8, the plug 10, and the contact plugs 14, 15, and 16. The barrier metal may be made of a material containing, for example, a titanium nitride as a main component. Each of the conductive film 9 and the conductive films 11, 12, and 13 may be made of a material containing a conductive material (for example, aluminum) as a main component.

The plug 6 extends to the plug 7 in the Z direction. The plug 7 extends to the penetration plug 8 in the Z direction. The penetration plug 8 extends in the Z direction and penetrates the memory cell array region MAR. The penetration plug 8 extends from the plug 7 to the conductive film 9 in the Z direction. The −Z-side end of the penetration plug 8 is in contact with the +Z-side surface of the conductive film 9, and the +Z-side end of the plug 10 is in contact with the −Z-side surface of the conductive film 9. The plug 10 extends from the conductive film 9 to the conductive film 11 in the Z direction. The −Z-side end of the plug 10 is in contact with the +Z-side surface of the conductive film 11, and the +Z-side end of the contact plug 14 is in contact with the −Z-side surface of the conductive film 11. The contact plug 14 extends from the conductive film 11 in the Z direction and reaches the peripheral circuit region PCR. Similarly, the contact plugs 15 and 16 extend from the conductive films 12 and 13 in the Z direction and reach the peripheral circuit region PCR, respectively.

With this structure, in some cases, hydrogen contained in the insulating layer IL and the interlayer insulating film IF in the memory cell array region MAR passes through the penetration plug 8, the conductive film 9, the plug 10, the conductive film 11, and the contact plug 14 in this order and enters the peripheral circuit region PCR. In addition, in some cases, hydrogen contained in the interlayer insulating film IF between the memory cell array region MAR and the substrate 2 in the Z direction passes through the conductive films 11 to 13 and the contact plugs 14 to 16 in this order and enters the peripheral circuit region PCR.

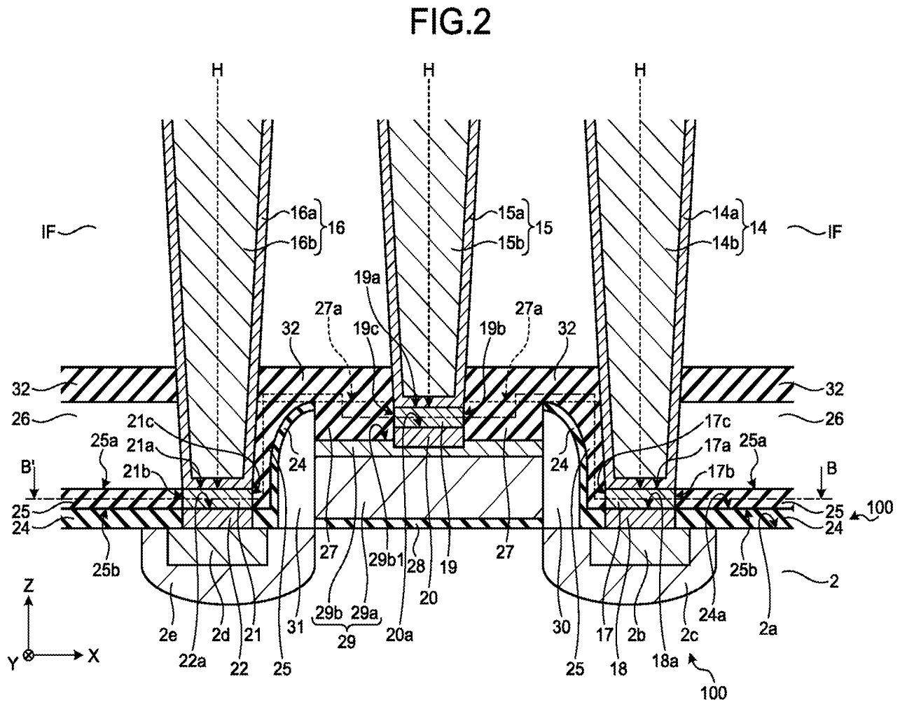

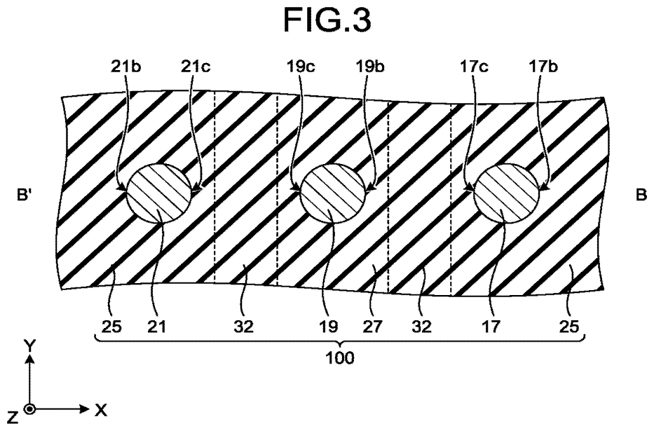

On the other hand, the peripheral circuit region PCR has a configuration of a continuous film 100 of silicon nitride films 25, 27, and 32 and titanium films 17, 19, and 21 as illustrated in FIGS. 2 and 3 as a hydrogen barrier structure. FIG. 2 is an enlarged cross-sectional view of a portion A in FIG. 1 and is a cross-sectional view illustrating the configuration of the continuous film 100 of the silicon nitride films 25, 27, and 32 and the titanium films 17, 19, and 21. FIG. 3 is a plan view illustrating the configuration of the continuous film 100 of the silicon nitride films 25, 27, and 32 and the titanium films 17, 19, and 21 and is a plan view illustrating a cross-sectional view of FIG. 2 taken along the line B-B′ (along the continuous film 100) when viewed from the +Z side.

Each of the silicon nitride films 25, 27, and 32 illustrated in FIG. 2 may be made of a material containing a silicon nitride as a main component. Each of the silicon nitride films 25, 27, and 32 extends substantially along the surface 2a of the substrate 2 between the substrate 2 and the stacked body 3 (refer to FIG. 1). The silicon nitride films 25, 27, and 32 constitute an integrated film. The silicon nitride films 27 and 32 cover the +Z side of a gate electrode 29 in the transistor constituting the peripheral circuit region PCR, and the silicon nitride film 25 covers the periphery of sidewalls 30 and 31 provided in the gate electrode 29.

Specifically, the silicon nitride film 25 extends in an XY direction around a silicon oxide film 24 provided in a liner shape on the transistor. The silicon nitride film 25 is raised to the +Z side in the vicinity of the sidewalls 30 and 31 and is in contact with the −Z-side surface of the silicon nitride film 32.

The silicon nitride film 27 extends in the XY direction on the +Z side of the gate electrode 29. The silicon nitride film 27 covers the +Z-side surface of the gate electrode 29. The +Z-side surface of the silicon nitride film 27 is covered with the silicon nitride film 32.

The silicon nitride film 32 is disposed on the +Z side of the silicon nitride films 25 and 27. The silicon nitride film 32 extends in the X and Y directions around the gate electrode 29 and the sidewalls 30 and 31 covering the +Z-side surface of, for example, an oxide film 26. The oxide film 26 is provided at a height in the Z direction substantially equal to that of the upper surface of the silicon nitride film 27 around the portion raised to the +Z side in the silicon nitride film 25 and is made of a material containing an oxide (for example, a silicon oxide) as a main component. The −Z-side surface of the silicon nitride film 32 in the vicinity the sidewalls 30 and 31 is in contact with the end surface of the portion that is raised to the +Z side of the silicon nitride film 25. The silicon nitride film 32 covers the +Z-side surface of the silicon nitride film 27 on the +Z side of the gate electrode 29.

The titanium film 17 may be made of a material containing titanium as a main component. The titanium film 17 is disposed between the contact plug 14 and a semiconductor region 2c in the Z direction. The titanium film 17 has a substantially plate shape corresponding to the bottom surface of the contact plug 14 when viewed from the Z direction. Side surfaces 17b and 17c of the titanium film 17 are connected to the silicon nitride film 25. In the vicinity of the side surface 17b of the titanium film 17, a +Z-side surface 17a of the titanium film 17 and an upper surface 25a of the silicon nitride film 25 have approximately the same Z-direction height. A barrier metal 14a is disposed on the bottom surface and the side surface of the contact plug 14, and a conductive member 14b is disposed inside the barrier metal 14a. The barrier metal 14a may be made of a material containing a titanium nitride as a main component. The conductive member 14b may be made of a material containing a conductive material (for example, tungsten) as a main component. The semiconductor region 2c is made of a material containing a semiconductor (for example, silicon) as a main component. The semiconductor region 2c may contain impurities (for example, boron) of a first conductivity type (for example, P-type) or may contain impurities (for example, phosphorus, arsenic) of a second conductivity type (for example, N-type).

A spacer film 18 having a substantially plate shape corresponding to the titanium film 17 is disposed between the titanium film 17 and the surface 2a of the substrate 2 when viewed from the Z direction. The spacer film 18 has a film thickness which is substantially equal to that of the silicon oxide film 24 having a liner shape. The silicon oxide film 24 extends along the surface 2a of the substrate 2 at a position adjacent to the spacer film 18 in the X and Y directions. The spacer film 18 has a +Z-side surface 18a having a height from the substrate 2 which is substantially equal to that of a +Z-side surface 24a of the silicon oxide film 24. The spacer film 18 has the +Z-side surface 18a having a height from the substrate 2 which is substantially equal to that of a −Z-side surface 25b of the silicon nitride film 25. Accordingly, it is easy to allow the +Z-side surface 17a of the titanium film 17 and the upper surface 25a of the silicon nitride film 25 to have substantially the same Z-direction height in the vicinity of the side surface 17b of the titanium film 17. The spacer film 18 may be made of a material containing a titanium nitride as a main component. A silicide region 2b is disposed in the vicinity of the surface 2a of the substrate 2 with which the spacer film 18 is in contact. The silicide region 2b may be made of a material containing titanium silicide as a main component.

In addition, when all the portions from the surface 2a of the substrate 2 to the height in the vicinity of the upper surface 25a of the silicon nitride film 25 are configured with the titanium film 17, the silicide region 2b generated by the reaction between the substrate 2 and the titanium film 17 excessively expands, and thus, there is a concern that a leak current between the contact plugs 14 and the substrate 2 may be increased. As illustrated in FIG. 2, since the spacer film 18 is disposed between the titanium film 17 and the surface 2a of the substrate 2, it is possible to suppress an increase in leak current due to excessive expansion of the silicide region 2b.

As illustrated in FIG. 3, the entire side surface of the titanium film 17 is covered with the silicon nitride film 25 when viewed from the Z direction. Accordingly, the continuous film 100 of the silicon nitride film 25 and the titanium film 17 can be formed without any gap in the vicinity of the titanium film 17, so that it is possible to reliably block the hydrogen entering from the +Z side via the contact plug 14.

The titanium film 19 illustrated in FIG. 2 may be made of a material containing titanium as a main component. The titanium film 19 is disposed between the contact plug 15 and a metal silicide film 29b constituting the gate electrode 29 in the transistor in the Z direction. The titanium film 19 has a substantially plate shape corresponding to the bottom surface of the contact plug 15 when viewed from the Z direction. Side surfaces 19b and 19c of the titanium film 19 are connected to the silicon nitride film 27. In the vicinity of the side surfaces 19b and 19c of the titanium film 19, a +Z-side surface 19a of the titanium film 19 and an upper surface 27a of the silicon nitride film 27 have substantially the same height in the Z direction. A barrier metal 15a is disposed on the bottom surface and the side surface of the contact plug 15, and a conductive member 15b is disposed inside the barrier metal 15a. The barrier metal 15a may be made of a material containing a titanium nitride as a main component. The conductive member 15b may be made of a material containing a conductive material (for example, tungsten) as a main component.

A spacer film 20 having a substantially plate shape corresponding to the titanium film 19 is disposed between the titanium film 19 and a +Z-side surface 29b1 of the gate electrode 29 when viewed from the Z direction. The spacer film 20 has a film thickness corresponding to the difference in film thickness between the silicon nitride film 27 and the titanium film 19. The silicon nitride film 27 covers a +Z-side surface 29b1 of the gate electrode 29 at a position adjacent to the spacer film 20 in the X and Y directions. The spacer film 20 has a +Z-side surface 20a of which height from the substrate 2 is higher than the +Z-side surface 29b1 of the gate electrode 29 and of which height from the substrate 2 is lower than the upper surface 27a of the silicon nitride film 27. Accordingly, it is easy to allow the +Z-side surface 19a of the titanium film 19 and the upper surface 27a of the silicon nitride film 27 to be substantially equal in height in the Z direction in the vicinity of the side surfaces 19b and 19c of the titanium film 19. The spacer film 20 may be made of a material containing a titanium nitride as a main component. The metal silicide film 29b is disposed in the vicinity of the +Z-side surface 29b1 of the gate electrode 29 with which the spacer film 20 is in contact. The metal silicide film 29b may be made of a material containing metal silicide (for example, a tungsten silicide) as a main component.

In addition, the gate electrode 29 is disposed on the gate insulating film 28 covering the surface 2a of the substrate 2 and has the polysilicon film 29a and the metal silicide film 29b. The polysilicon film 29a may be made of a material containing polysilicon as a main component. The polysilicon film 29a may contain impurities (for example, boron) of a first conductivity type (for example, P-type) and may contain impurities (for example, phosphorus, arsenic) of a second conductivity type (for example, N-type).

As illustrated in FIG. 3, the entire side surface of the titanium film 19 is covered with the silicon nitride film 27 when viewed from the Z direction. Accordingly, the continuous film 100 of the silicon nitride films 27 and 32 and the titanium film 19 can be formed in the vicinity of the titanium film 19 without any gap, so that it is possible to reliably block hydrogen entering from the +Z side via the contact plug 15.

The titanium film 21 illustrated in FIG. 2 may be made of a material containing titanium as a main component. The titanium film 21 is disposed between the contact plug 16 and a semiconductor region 2e in the Z direction. The titanium film 21 has a substantially plate shape corresponding to the bottom surface of the contact plug 16 when viewed from the Z direction. Side surfaces 21b and 21c of the titanium film 21 are connected to the silicon nitride film 25. In the vicinity of the side surface 21b of the titanium film 21, a +Z-side surface 21a of the titanium film 21 and the upper surface 25a of the silicon nitride film 25 have substantially the same height in the Z direction. A barrier metal 16a is disposed on the bottom surface and the side surface of the contact plug 16, and a conductive member 16b is disposed inside the barrier metal 16a. The barrier metal 16a may be made of a material containing a titanium nitride as a main component. The conductive member 16b may be made of a material containing a conductive material (for example, tungsten) as a main component. The semiconductor region 2e is made of a material containing a semiconductor (for example, silicon) as a main component. The semiconductor region 2e may contain impurities (for example, boron) of a first conductivity type (for example, P-type) or may contain impurities (for example, phosphorus, arsenic) of a second conductivity type (for example, N-type).

A spacer film 22 having a substantially plate shape corresponding to the titanium film 21 is disposed between the titanium film 21 and the surface 2a of the substrate 2 when viewed from the Z direction. The spacer film 22 has a film thickness which is substantially equal to that of the silicon oxide film 24 having a liner shape. The spacer film 22 has a +Z-side surface 22a having a height from the substrate 2 which is substantially equal to that of the −Z-side surface 25b of the silicon nitride film 25. Accordingly, it is easy to allow the +Z-side surface 21a of the titanium film 21 and the upper surface 25a of the silicon nitride film 25 to have substantially the same the Z-direction height in the vicinity of the side surface 21b of the titanium film 21. The spacer film 22 may be made of a material containing a titanium nitride as a main component. A silicide region 2d is disposed in the vicinity of the surface 2a of the substrate 2 with which the spacer film 22 is in contact. The silicide region 2d may be made of a material containing titanium silicide as a main component.

As illustrated in FIG. 3, the entire side surface of the titanium film 21 is covered with the silicon nitride film 25 when viewed from the Z direction. Accordingly, the continuous film 100 of the silicon nitride film 25 and the titanium film 21 can be formed without any gap in the vicinity of the titanium film 21, so that it is possible to reliably block the hydrogen entering from the +Z side via the contact plug 16. In addition, as illustrated in FIG. 2, since the spacer film 22 is disposed between the titanium film 21 and the surface 2a of the substrate 2, it is possible to suppress an increase in leak current due to excessive expansion of the silicide region 2d.

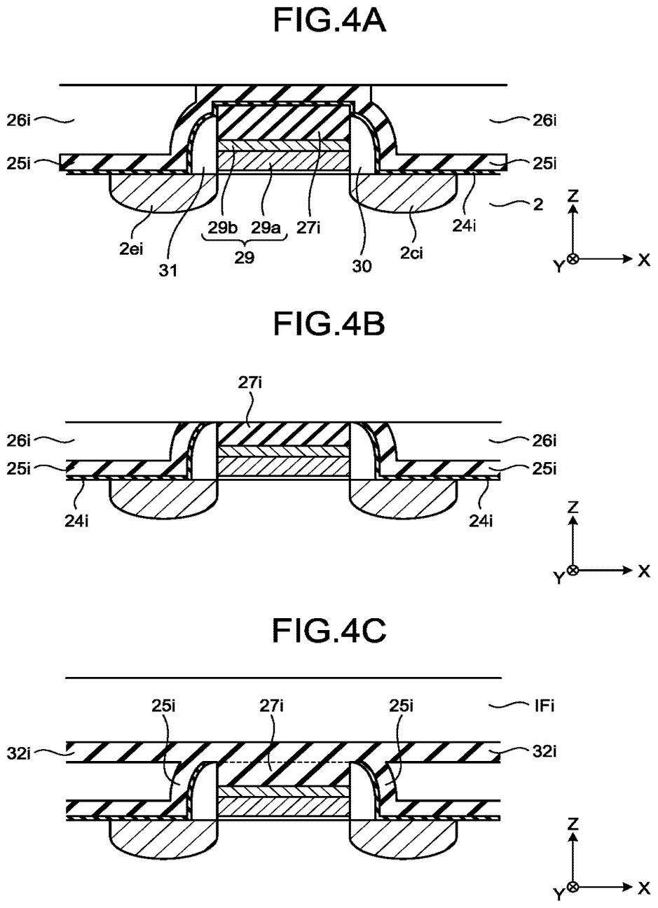

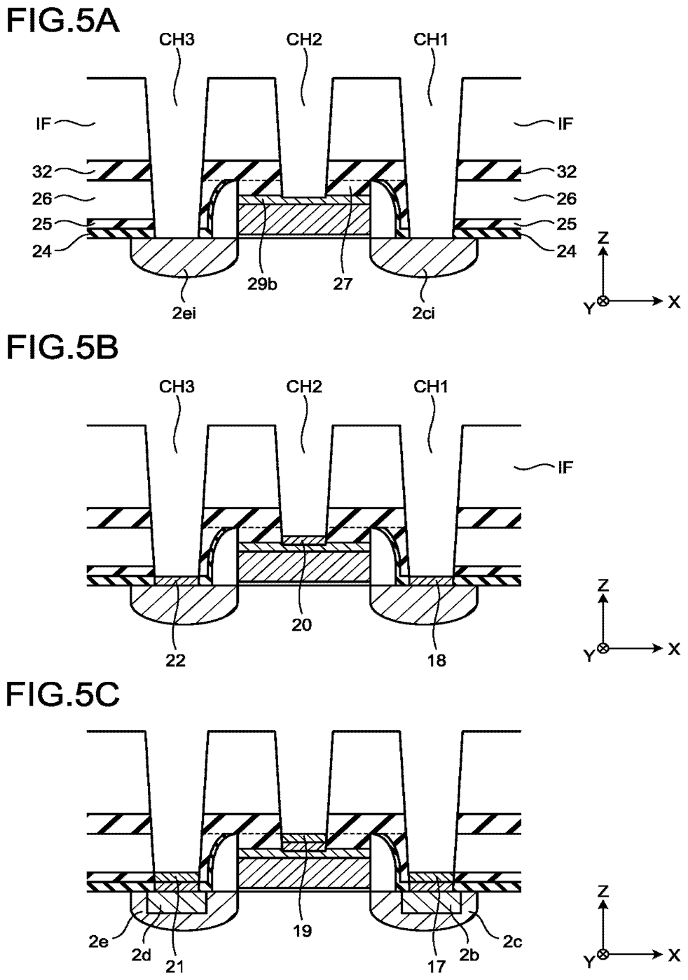

Next, a method of manufacturing the semiconductor device 1 will be described with reference to FIGS. 4A to 4C and FIGS. 5A to 5C. FIGS. 4A to 4C and FIGS. 5A to 5C are cross-sectional views for processes illustrating the method of manufacturing the semiconductor device 1.

In the process illustrated in FIG. 4A, the substrate 2 is prepared. The substrate 2 is made of a material containing a semiconductor (for example, silicon) as a main component. A polysilicon film, a metal silicide film (for example, a tungsten silicide film), and a silicon nitride film are sequentially deposited on the substrate 2, and after that, patterning is performed in a shape corresponding to the gate, so that the gate electrode 29 including the polysilicon film 29a and the metal silicide film 29b and a silicon nitride film 27i disposed on the gate electrode 29 are formed. Then, impurities are introduced into the substrate 2 by using the gate electrode 29 as a mask to form semiconductor regions 2ci and 2ei. The impurities introduced into the substrate 2 may be impurities (for example, boron) of a first conductivity type (for example, P-type) or may be impurities (for example, phosphorus, arsenic) of a second conductivity type (for example, N-type). Then, the sidewalls 31 and 30 are formed on the side surfaces of the gate electrode 29, and a silicon oxide film 24i covering the semiconductor regions 2ci and 2ei, the gate electrode 29, the silicon nitride film 27i, and the sidewalls 31 and 30 is deposited. In addition, a silicon nitride film 25i and a silicon oxide film 26i are sequentially deposited so as to cover the silicon oxide film 24i. Thereafter, a planarization process of polishing the +Z side is performed by using the silicon nitride film 25i as a stopper, and thus, the silicon oxide film 26i located above the gate electrode 29, the silicon nitride film 27i and the sidewalls 31 and 30 (in the +Z side) is removed.

In the process illustrated in FIG. 4B, the entire +Z-side surface is etched back until the silicon nitride film 27i is exposed, and the portion of the silicon oxide film 24i covering the silicon nitride film 27i is removed. At this time, the +Z-side end of the portion of the silicon nitride film 25i which is raised to the +Z side is exposed around the silicon nitride film 27i together with the silicon nitride film 27i.

In the process illustrated in FIG. 4C, a silicon nitride film 32i is deposited. Accordingly, the silicon nitride films 25i, 27i, and 32i are formed as an integrated film. Furthermore, an interlayer insulating film IFi is deposited on the silicon nitride film 32i.

In the process illustrated in FIG. 5A, a resist pattern is formed in which the formation positions of the contact plugs 14, 15, and 16 are opened on the interlayer insulating film IFi. By using the resist pattern as a mask, anisotropic etching is performed by RIE or the like until the semiconductor region 2ci, the metal silicide film 29b, and the semiconductor region 2ei are exposed, so that contact holes CH1, CH2, and CH3 are formed.

In the process illustrated in FIG. 5B, a thin film (for example, a titanium film) for forming a silicide (not illustrated) and a spacer film (for example, a titanium nitride film) 18, 20 and 22 are sequentially deposited selectively on the bottom surfaces of the contact holes CH1, CH2, and CH3 by a PVD method or the like. At this time, in order to selectively deposit on the bottom surfaces of the contact holes CH1, CH2, and CH3 without being deposited on the side surfaces of the contact holes CH1, CH2, and CH3, the processing conditions in the PVD method or the like can be adjusted under appropriate conditions (for example, an acceleration voltage can be slightly heightened).

In the process illustrated in FIG. 5C, the titanium films 17, 19, and 21 are deposited on the spacer films 18, 20, and 22 (in the +Z side) in the contact holes CH1, CH2, and CH3 by the PVD method or the like. At this time, the silicide regions 2b and 2d can be formed in the semiconductor regions 2c and 2e.

Then, barrier metals (for example, titanium nitride films) 14b, 15b, and 16b are deposited on the bottom and side surfaces of the contact holes CH1, CH2, and CH3, and the conductive members 14a, 15a, and 16a are buried inside the barrier metals 14b, 15b, and 16b, so that the contact plugs 14, 15, and 16 illustrated in FIG. 2 are formed.

As described above, in the embodiment, in the semiconductor device 1, the continuous film 100 of the silicon nitride films 25, 27, and 32 and the titanium films 17, 19, and 21 is disposed as the hydrogen barrier structure between the substrate 2 and the stacked body 3 in the stacking direction (Z direction). Accordingly, entering of hydrogen into the peripheral circuit region PCR can be blocked, and thus, it is possible to suppress deterioration in characteristic of the semiconductor device 1.

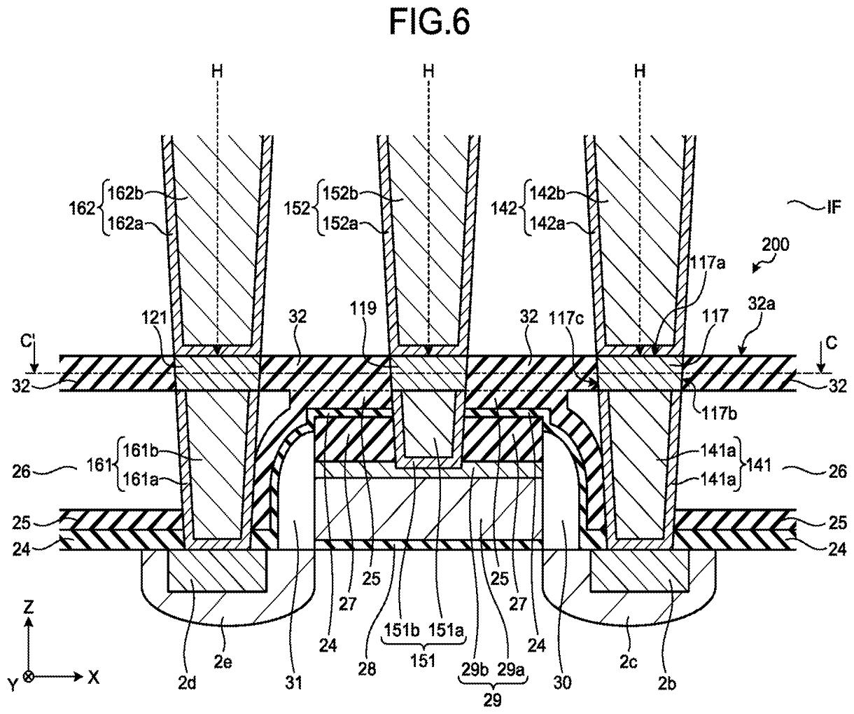

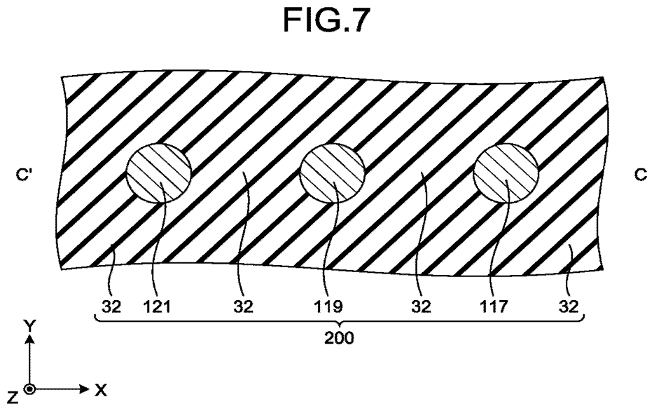

Furthermore, as Modified Example of the embodiment, the continuous film of the silicon nitride film and the titanium film may be configured so that the heights of the silicon nitride film and the titanium films are approximately equal to each other in the Z direction. For example, the continuous film 200 of the silicon nitride film 32 and titanium films 117, 119, and 121 may be configured as illustrated in FIGS. 6 and 7. FIG. 6 is an enlarged cross-sectional view of the portion corresponding to the portion A in FIG. 1 and is a cross-sectional view illustrating the configuration of the continuous film 200 of the silicon nitride film 32 and the titanium films 117, 119, and 121. FIG. 7 is a plan view illustrating the configuration of the continuous film 200 of the silicon nitride film 32 and the titanium films 117, 119, and 121 and is a plan view illustrating a cross-sectional view of FIG. 6 taken along the C-C′ line (along the continuous film 200) when viewed from the +Z side.

As illustrated in FIG. 6, in the continuous film 200, the heights of the silicon nitride film 32 and the titanium films 117, 119, and 121 in the Z direction are approximately equal to each other. In the structure of the continuous film 200, a spacer film is unnecessary.

The titanium film 117 may be made of a material containing titanium as a main component. The titanium film 117 is disposed between a contact plug 142 and the contact plug 141 in the Z direction. The titanium film 117 has a substantially plate shape corresponding to the bottom surface of the contact plug 142 when viewed from the Z direction. Side surfaces 117b and 117c of the titanium film 117 are connected to the silicon nitride film 32. In the vicinity of side surfaces 117b and 117c of the titanium film 117, a +Z-side surface 117a of the titanium film 117 and an upper surface 32a of the silicon nitride film 32 have substantially the same height in the Z direction.

The −Z-side surface of the contact plug 142 is in contact with the +Z-side surface 117a of the titanium film 117. In addition, the −Z-side surface of the titanium film 117 is in contact with the +Z-side surface of the contact plug 141. The contact plug 142 is disposed between the titanium film 117 and the conductive film 11 (refer to FIG. 1), and the contact plug 141 is disposed between the titanium film 117 and the semiconductor region 2c. A barrier metal 142a is disposed on the bottom surface and the side surface of the contact plug 142, and a conductive member 142b is disposed inside the barrier metal 142a. A barrier metal 141a is disposed on the bottom surface and the side surface of the contact plug 141, and a conductive member 141b is disposed inside the barrier metal 141a. Each of the barrier metals 142a and 141a may be made of a material containing a titanium nitride as a main component. Each of the conductive members 142b and 141b may be made of a material containing a conductive material (for example, tungsten) as a main component.

As illustrated in FIG. 7, the entire side surface of the titanium film 117 is covered with the silicon nitride film 32 when viewed from the Z direction. Accordingly, the continuous film 200 of the silicon nitride film 32 and the titanium film 117 can be formed without any gap in the vicinity of the titanium film 117, so that it is possible to reliably block the hydrogen entering from the +Z-side via the contact plug 142.

The titanium film 119 illustrated in FIG. 6 may be made of a material containing titanium as a main component. The titanium film 119 is disposed between a contact plug 152 and a contact plug 151 in the Z direction. The titanium film 119 has a substantially plate shape corresponding to the bottom surface of the contact plug 152 when viewed from the Z direction. The side surface of the titanium film 119 is connected to the silicon nitride film 32. In the vicinity of the side surface of the titanium film 119, the +Z-side surface of the titanium film 119 and the upper surface 32a of the silicon nitride film 32 have substantially the same height in the Z direction.

The −Z-side surface of the contact plug 152 is in contact with the +Z-side surface of the titanium film 119. In addition, the −Z-side surface of the titanium film 119 is in contact with the +Z-side surface of the contact plug 151. The contact plug 152 is disposed between the titanium film 119 and the conductive film 12 (refer to FIG. 1), and the contact plug 151 is disposed between the titanium film 119 and the gate electrode 29. A barrier metal 152a is disposed on the bottom surface and the side surface of the contact plug 152, and a conductive member 152b is disposed inside the barrier metal 152a. A barrier metal 151a is disposed on the bottom surface and the side surface of the contact plug 151, and a conductive member 151b is disposed inside the barrier metal 151a. Each of the barrier metals 152a and 151a may be made of a material containing a titanium nitride as a main component. Each of the conductive members 152b and 151b may be made of a material containing a conductive material (for example, tungsten) as a main component.

As illustrated in FIG. 7, the entire side surface of the titanium film 119 is covered with the silicon nitride film 32 when viewed from the Z direction. Accordingly, the continuous film 200 of the silicon nitride film 32 and the titanium film 119 can be formed without any gap in the vicinity of the titanium film 119, so that it is possible to reliably block the hydrogen entering from the +Z-side via the contact plug 152.

The titanium film 121 illustrated in FIG. 6 may be made of a material containing titanium as a main component. The titanium film 121 is disposed between a contact plug 162 and a contact plug 161 in the Z direction. The titanium film 121 has a substantially plate shape corresponding to the bottom surface of the contact plug 162 when viewed from the Z direction. The side surface of the titanium film 121 is connected to the silicon nitride film 32. In the vicinity of the side surface of the titanium film 121, the +Z-side surface of the titanium film 121 and the upper surface 32a of the silicon nitride film 32 have substantially the same height in the Z direction.

The −Z-side surface of the contact plug 162 is in contact with the +Z-side surface of the titanium film 121. In addition, the −Z-side surface of the titanium film 121 is in contact with the +Z-side surface of the contact plug 161. The contact plug 162 is disposed between the titanium film 121 and the conductive film 13 (refer to FIG. 1), and the contact plug 161 is disposed between the titanium film 121 and the semiconductor region 2e. A barrier metal 162a is disposed on the bottom surface and the side surface of the contact plug 162, and a conductive member 162b is disposed inside the barrier metal 162a. A barrier metal 161a is disposed on the bottom surface and the side surface of the contact plug 161, and a conductive member 161b is disposed inside the barrier metal 161a. Each of the barrier metals 162a and 161a may be made of a material containing a titanium nitride as a main component. Each of the conductive members 162b and 161b may be made of a material containing a conductive material (for example, tungsten) as a main component.

As illustrated in FIG. 7, the entire side surface of the titanium film 121 is covered with the silicon nitride film 32 when viewed from the Z direction. Accordingly, the continuous film 200 of the silicon nitride film 32 and the titanium film 121 can be formed without any gap in the vicinity of the titanium film 121, so that it is possible to reliably block the hydrogen entering from the +Z-side via the contact plug 162.

The continuous film 200 may be formed by the following method of manufacturing the semiconductor device 1. First, after the process illustrated in FIG. 4A is performed, the silicon nitride film 32i and the interlayer insulating film IFi are sequentially deposited on the +Z-side surface, and further the process illustrated in FIG. 5A is performed to form the contact holes CH1, CH2, and CH3. Herein, in Modified Example of the embodiment, since the hydrogen entering from the +Z-side can be blocked by the continuous film 200 disposed at the height in the Z direction corresponding to the silicon nitride film 32, the entire-surface etch back performed so as to remove the portion of the silicon oxide film 24i covering the silicon nitride film 27i in the process illustrated in FIG. 4B is omitted.

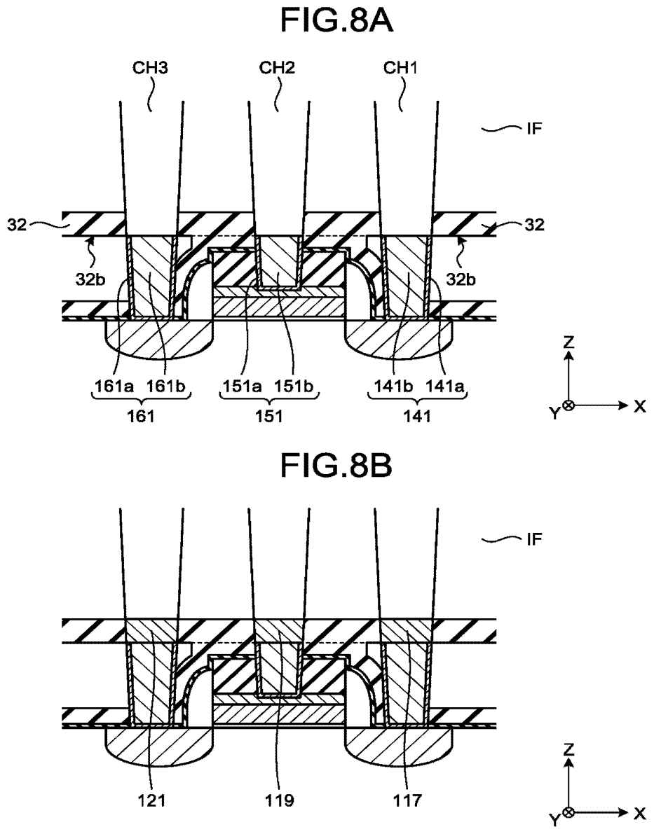

In the process illustrated in FIG. 8A, barrier metals (for example, a titanium nitride film) 141a, 151a, and 161a are deposited on the bottom and side surfaces of the contact holes CH1, CH2, and CH3, up to the Z-direction height of a −Z-side surface 32b of the silicon nitride film 32. In addition, the conductive members 141b, 151b, and 161b are buried up to the Z-direction height of the −Z-side surface 32b of the silicon nitride film 32. Accordingly, the contact plugs 141, 151, and 161 are formed.

In the process illustrated in FIG. 8B, the titanium films 117, 119, and 121 are deposited on the contact plugs 141, 151, and 161 (in the +Z side) in the contact holes CH1, CH2, and CH3 by a PVD method or the like.

Then, barrier metals (for example, titanium nitride films) 142a, 152a, and 162a are deposited on the titanium films 117, 119, and 121 (in the +Z side) in the contact holes CH1, CH2, and CH3, and the conductive members 142b, 152b, and 162b are buried in the inner side to form the contact plugs 142, 152, and 162 illustrated in FIG. 6.

In this manner, in Modified Example of the embodiment, the continuous film 200 of the silicon nitride film 32 and the titanium films 117, 119, and 121 is disposed. Accordingly, entering of hydrogen into the peripheral circuit region PCR can be blocked, and thus, it is possible to suppress deterioration in characteristic of the semiconductor device 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a stacked body disposed above a substrate, the stacked body including a conductive layer and an insulating layer disposed repeatedly in a stacking direction;
a silicon nitride film extending along a surface of the substrate between the substrate and the stacked body; and
a titanium film extending along the surface of the substrate between the substrate and the stacked body, the titanium film constituting a film continuous with the silicon nitride film.

2. The semiconductor device according to claim 1, wherein
a side surface of the titanium film is connected to the silicon nitride film.

3. The semiconductor device according to claim 1, wherein
an entire side surface of the titanium film is covered with the silicon nitride film when viewed from a direction perpendicular to the substrate.

4. The semiconductor device according to claim 1, wherein
an upper surface of the titanium film and an upper surface of the silicon nitride film have substantially equal height from the substrate.

5. The semiconductor device according to claim 1, further comprising
a spacer film disposed between the titanium film and the substrate in the stacking direction.

6. The semiconductor device according to claim 1, wherein
the titanium film is disposed between a first conductive portion and a second conductive portion in the stacking direction.

7. The semiconductor device according to claim 6, wherein
the first conductive portion is a contact plug,
the titanium film has a substantially plate shape corresponding to a bottom surface of the contact plug, and
the second conductive portion is a semiconductor region containing impurities.

8. The semiconductor device according to claim 7, further comprising
a spacer film disposed between the titanium film and the semiconductor region in the stacking direction.

9. The semiconductor device according to claim 8, further comprising
a silicon oxide film disposed between the silicon nitride film and the substrate in the stacking direction,
wherein the silicon oxide film extends along the surface of the substrate at a position adjacent to the spacer film in a substrate plane direction.

10. The semiconductor device according to claim 6, wherein
the first conductive portion is a contact plug,
the titanium film has a substantially plate shape corresponding to a bottom surface of the contact plug, and
the second conductive portion is a gate electrode.

11. The semiconductor device according to claim 10, further comprising
a spacer film disposed between the titanium film and the gate electrode in the stacking direction.

12. The semiconductor device according to claim 11, wherein
the silicon nitride film covers an upper surface of the gate electrode at a position adjacent to the spacer film in a substrate plane direction, and
an upper surface of the spacer film is higher than the upper surface of the gate electrode in height from the substrate and is lower than an upper surface of the silicon nitride film in height from the substrate.

13. The semiconductor device according to claim 6, wherein
the first conductive portion is an upper contact plug,
the titanium film has a substantially plate shape corresponding to a bottom surface of the upper contact plug, and
the second conductive portion is a lower contact plug.

14. The semiconductor device according to claim 13, wherein
the titanium film is in contact with the bottom surface of the upper contact plug and is in contact with an upper surface of the lower contact plug.

15. The semiconductor device according to claim 1, wherein
the titanium film includes:
a first film disposed between a first contact plug and a first semiconductor region containing impurities in the stacking direction; and
a second film disposed between a second contact plug and a gate electrode in the stacking direction, and
wherein the silicon nitride film includes:
a first portion extending along the surface of the substrate and connected to a side surface of the first film;
a second portion extending along an upper surface of the gate electrode and connected to a side surface of the second film; and
a third portion extending in the stacking direction and connecting the first portion and the second portion.

16. The semiconductor device according to claim 15, wherein
the titanium film further includes
a third film disposed between a third contact plug and a second semiconductor region containing impurities in the stacking direction, and
the silicon nitride film further includes:
a fourth portion extending along the surface of the substrate and connected to a side surface of the third film; and
a fifth portion extending in the stacking direction and connecting the second portion and the fourth portion.

17. The semiconductor device according to claim 15, further comprising:
a first spacer film disposed between the first film and the first semiconductor region in the stacking direction; and
a second spacer film disposed between the second film and the gate electrode in the stacking direction.

18. The semiconductor device according to claim 1, wherein
the titanium film includes:
a first film disposed between a first upper contact plug and a first lower contact plug in the stacking direction; and
a second film disposed between a second upper contact plug and a second lower contact plug in the stacking direction, and
the silicon nitride film includes:
a first portion extending along the surface of the substrate and connected to a side surface of the first film;
a second portion extending along the surface of the substrate and connected to a side surface of the second film; and
a third portion extending along the surface of the substrate and connecting the first portion and the second portion.

19. The semiconductor device according to claim 18, wherein
the titanium film further includes
a third film disposed between a third upper contact plug and a third lower contact plug in the stacking direction, and
the silicon nitride film further includes:
a fourth portion extending along the surface of the substrate and connected to a side surface of the third film; and
a fifth portion extending along the surface of the substrate and connecting the second portion and the fourth portion.

20. The semiconductor device according to claim 18, wherein
the first film is in contact with a bottom surface of the first upper contact plug and is in contact with an upper surface of the first lower contact plug, and
the second film is in contact with a bottom surface of the second upper contact plug and is in contact with an upper surface of the second lower contact plug.
